(19) United States
(12) Patent Application Publication
(10) Pub. No.: US 2007/0070800 A1
(43) Pub. Date: Mar. 29, 2007

(54) Externally worn vasovagal syncope detection device

(76) Inventors: Nathalie Virag, Chemin des Vignes (CH); Rolf Vetter, Csem, Jacquet-Droz 1 (CH)

Correspondence Address: MEDTRONIC, INC., 710 MEDTRONIC PARK, MINNEAPOLIS, MN, 55432-9924, US

(21) Appl. No.: 11/235,943

(22) Filed: Sep. 27, 2005

(51) Int. Cl. G11C 8/00

(52) U.S. Cl. 365/244

(57) ABSTRACT

A device is worn adjacent to tissue of a patient to detect vasovagal syncope (VVS). The device includes a photoplethysmographic sensor that measures a plethysmographic signal through tissue, and a processor that derives an indicator of an autonomous nervous system (ANS) activity from the plethysmographic signal and estimates a probability that the patient will experience VVS as a function of the indicator.

### BACKGROUND OF THE INVENTION

Vasovagal syncope (VVS), a condition marked by a sudden drop in heart rate and blood pressure resulting in fainting, is unpleasant for a patient and potentially dangerous. For example, fainting can lead to injuries from falls and increase the risk of motor vehicle accidents. VVS affects many thousands of patients, some of whom are at risk of recurrent episodes of VVS.

It is important to detect indicators of VVS and alert a patient well before the onset of VVS. This gives the patient sufficient time to take appropriate measures to avoid injuries that may occur due to fainting. For example, if given an early warning prior to VVS, the patient may have enough time to sit down or stop activities to avoid accidents. Commonly assigned U.S. Pat. App. Pub. 2004/0215263 A1, entitled “Detection of Vasovagal Syncope,” discloses the use of an implantable device and an associated algorithm to detect indicators of VVS and deliver therapies to address the potential onset of VVS.

### BRIEF SUMMARY OF THE INVENTION

Most of the embodiments of the disclosure relate to a device that is worn by a patient to detect vasovagal syncope (VVS). The device includes a photoplethysmographic sensor and a processor that derives an indicator of an autonomous nervous system (ANS) activity from a plethysmographic signal. The processor estimates a probability that the patient will experience VVS as a function of the indicator.

### BRIEF DESCRIPTION OF THE DRAWINGS

FIG. 1 is a bottom view of an externally worn device for detecting vasovagal syncope (VVS) in a patient.

FIG. 2 is a cross-sectional view of the device shown in FIG. 1.

FIG. 3 is a flow diagram showing a technique for early detection and warning of VVS according to an embodiment of the present invention.

FIG. 4 is a block diagram showing the flow of information in detecting the onset of VVS according to the present invention.

FIG. 5 is a flow diagram illustrating a technique for normalization of an indicator of autonomic nervous system (ANS) activity.

FIG. 6 shows four timelines illustrating the relationship among physiological signals that include indicators of ANS activity and the onset of VVS.

### DETAILED DESCRIPTION

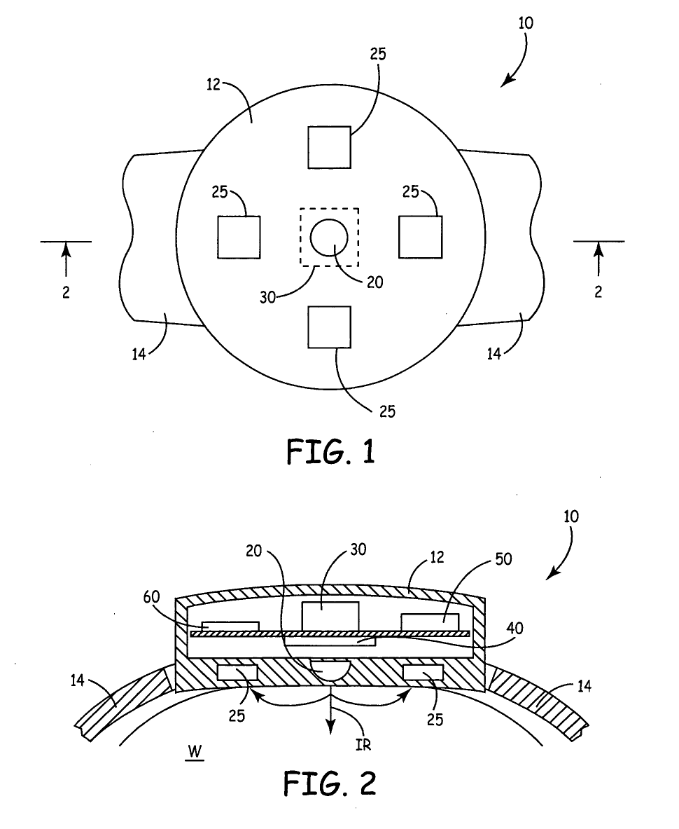

FIG. 1 shows a schematic bottom view and FIG. 2 shows a cross-sectional view of vasovagal syncope (VVS) detection device 10, which is a warning device configured to be externally worn in contact with human tissue to detect VVS in a patient. VVS detection device 10 uses photoplethysmographic (PPG) sensing to measure a physiological signal through human tissue. An indicator of autonomous nervous system (ANS) activity is derived from the physiological signal and is used to estimate a probability that the patient will experience VVS. Based on that estimated probability, VVS detection device 10 provides advance warning to the patient to help avoid injuries associated with an episode of VVS.

VVS detection device 10 includes housing 12 and attachment element 14 for attachment to a patient's wrist W. Located within housing 12 are light source 20, light detectors 25, motion detecting device 30, digital signal processor (DSP) 40, warning device 50, and memory unit 60.

Light source 20, which in one embodiment is an infrared (IR) light emitting device, emits radiant energy directed at human body tissue (e.g., wrist W). Light source 20 is located near or in contact with the patient's skin when device 10 is worn on wrist W.

Light detectors 25, which may be IR photodiodes, detect the intensity of the radiant energy that returns to device 10 after propagation through body tissue. Light detectors 25 are disposed substantially symmetrically and equidistantly around light source 20.

Motion detecting device 30 is disposed, for example, in an upper portion of housing 12. In one embodiment, motion detecting device 30 is a three-axis accelerometer or another device for providing data representative of the acceleration to which device 10 is subjected.

DSP 40 processes the signals produced by light detectors 25 and motion detecting device 30. Alternatively, these signals may be processed by an external processing unit linked to device 10 (by means of a direct or wireless connection).

Warning device 50, which is also disposed in an upper portion of housing 12, provides an output to the wearer of device 10 when the probability of VVS occurring exceeds a threshold probability. The output may be in the form of a visual signal, auditory signal, or other perceptible signal. For example, warning device 50 may include a visual alarm (such as a light or display), an auditory alarm (such as a piezoelectric alarm or a buzzer), or a vibrating device.

Memory unit 60 is in communication with processor 40 and stores data, programming, and other information relating to the operation of device 10. Memory unit 60 may include, for example, electrically erasable programmable read-only memory (EEPROM), erasable programmable read-only memory (EPROM), programmable read-only memory (PROM), or random access memory (RAM).

The operation of device 10 relies upon photoplethysmography (PPG), an electro-optic technique of detecting the cardiovascular pulse wave in the human body. Periodic pulsations of arterial blood volume cause the optical absorption characteristics of body tissue to change. To detect the changing optical absorption characteristics, radiant energy is emitted from light source 20 into the body tissue of wrist W. Light detectors 25 sense radiant energy that has propagated through the tissue and returned to device 10 to produce the plethysmographic signal.

When light propagates through body tissue, several mechanisms are involved in the interaction between the light and the tissue, including reflection, refraction, scattering, and absorption. Reflection and refraction occur at the interfaces between device 10 and the patient. Scattering is due to the microscopic variations of the dielectric properties of the tissue. These variations are due to the cell membranes and the sub-cellular components (e.g., mitochondria and nuclei). For IR radiation, absorption is mainly due to the presence of chromophores such as hemoglobin, myoglobin, cytochrome, melanin, lipid, bilirubin, and water.

Under ideal steady-state conditions, the IR signal received by light detectors 25 contains both a constant (DC) and a time-varying (AC) component. The DC component is generally ascribed to a baseline absorption of the IR signal by blood, soft tissue, and non-expansive tissue such as bone, as well as to reflective loss. The AC component indicates a modification of the effective path length through the tissue for the IR signal due to the expansion and contraction of the tissue from varying blood pressure.

For IR wavelengths and near IR wavelengths, light propagation through the tissue is primarily affected by scattering and absorption. The Beer-Lambert equation describes the phenomenon of light absorption in biological tissue:

$${I}_{O} ( t ) = {I}_{i} ( t ) \cdot exp ( - {\sum }_{j = 1}^{n} {ɛ}_{λ , j} {c}_{j} ( t ) {d}_{j} ( t ) )$$

where lᵢ(t) and lₒ(t) are the input and output light intensity, respectively, λ is the wavelength of light, and cⱼ(t), dⱼ(t), and ∈ _{λ,j} represent, respectively, the concentration, the spanning path length, and the absorption coefficient of the different components of the tissue. For further information, see “Noise-Resistant Pulse Oximetry Using a Synthetic Reference Signal,” by F. M. Coetzee et al., IEEE Transactions on Biomedical Engineering, vol. 47, pp. 1018-1026, August 2000, and “A Review of the Optical Properties of Biological Tissues,” by W.-F. Cheong et al., IEEE Journal of Quantum Electronics, vol. 26, pp. 2166-2185, 1990.

Voluntary or involuntary movements by the patient who is wearing VVS detection device 10 may create motion-related artifacts that corrupt the PPG signal. These motion artifacts are generally caused by modification of the optical properties of the tissue (e.g., modification of blood pressure, modification of the optical path, etc.) due to movement. These modifications affect the corresponding components of the Beer-Lambert equation. Motion detecting device 30 detects motion, and DSP 40 employs an algorithm to remove motion artifacts produced by the detected motion from the measured plethysmographic signal.

Because variations of optical tissue characteristics are related to variations in subcutaneous blood flow, the plethysmographic signals sensed by light detectors 25 may be used to estimate various physiological parameters of the patient. For example, estimates of the R-R interval (i.e., the interval between ventricular activations) and blood pressure may be derived from the plethysmographic signal. More specifically, the intervals between successive minima of the plethysmographic signal correspond to the instantaneous heart interval of the patient, and changes in the magnitude of successive minima of the plethysmographic signal are related to fluctuations in systolic pressure. After an analog-to-digital conversion, processor 40 derives the R-R interval and the blood pressure from the plethysmographic signal.

The R-R interval is directly related to heart rate and heart interval, both of which are indicators of autonomic nervous system (ANS) activity. ANS activity may signal the onset of VVS. In addition, variabilities in arterial blood volume (i.e., changes in blood pressure) also signify ANS activity.

The ANS includes two subsystems: the sympathetic nervous system and the parasympathetic nervous system. Under some conditions sympathetic nervous system activity is dominant over parasympathetic nervous system activity, while under other conditions, parasympathetic nervous system activity is dominant over sympathetic nervous system activity. The dominance of the sympathetic system over the parasympathetic system, or vice versa, is called the “balance between sympathetic and parasympathetic activity,” or “sympatho-vagal balance.” “Vagal” generally refers to the vagus nerve, the major nerve of the parasympathetic nervous system.

In general, the sympathetic system promotes responses that prepare the body for strenuous physical activity, such as physical activity that may be required in a stressful or emergency situation. The parasympathetic system is generally dominant in relaxed situations.

Sympathetic or parasympathetic dominance may vary from organ to organ. For example, the heart may experience a shift in the balance between sympathetic and parasympathetic activity, even though other organs may not. Sympathetic stimulation on the heart generally results in an increased heart rate and increased force of contraction, while parasympathetic stimulation of the heart generally has the opposite effect. Sympathetic stimulation also results in constriction of blood vessels for most organs and dilation of veins that supply blood to the heart, such as, for example, the coronary vein.

A decrease in cardiac sympathetic activity and an increase in cardiac parasympathetic activity may precede an episode of VVS. When parasympathetic activity rises, heart rate may decrease and blood vessels may become less constricted, resulting in a decrease in blood pressure. A decrease in heart rate and blood pressure typically precedes an episode of VVS.

When this decrease in heart rate and blood pressure is accompanied by an increase in orthostatic stress, the probability of an episode of VVS occurring in the patient increases. An increase in orthostatic stress may be caused by a posture transition from a supine to an upright position, or by an activity transition from running or walking to standing or sitting. The movements detected by motion detecting device 30 may be analyzed by processor 40 to determine whether a posture transition of a kind that may lead to VVS has occurred.

In addition, if motion detecting device 30 detects continuous motion (e.g., walking or running), processor 40 stops processing of the motion signals since VVS generally occurs during periods of motionless orthostatic stress. By coordinating operation of processor 40 with motion detected by motion detecting device 30, power consumption in device 10 can be reduced.

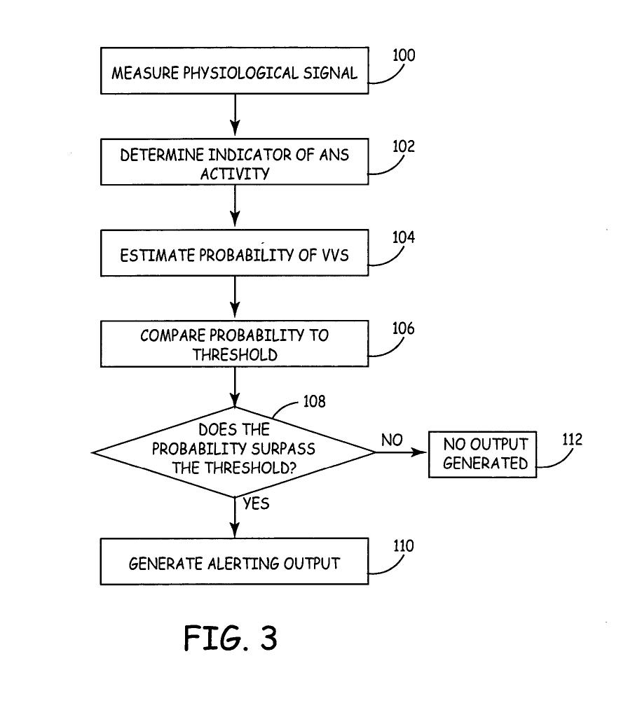

FIG. 3 is a flow diagram showing a technique for early detection and warning of VVS. A physiological signal is first derived from the plethysmographic signal obtained using the PPG-based measuring technique employed by device 10 (step 100). In one embodiment, deriving of the physiological signal from the plethysmographic signal is triggered by a posture or activity transition as detected by motion detecting device 30. An indicator of ANS activity is then determined from the physiological signal (step 102). Processor 40 analyzes the indicator of ANS activity to estimate a probability that an episode of VVS will occur (step 104). Generally speaking, the analysis and estimation result in more reliable predictors of VVS when the analysis of ANS activity is based upon a cumulative measure of a particular ANS indicator and physiological signals. Examples of analysis and estimation techniques will be described below.

The probability that an episode of VVS will occur is compared to a threshold (step 106). If the probability that an episode of VVS will occur exceeds the threshold (step 108), then warning device 50 generates an alerting output (step 110) to alert the patient that an episode of VVS is likely to occur. If the probability that an episode of VVS will occur does not exceed the threshold (step 108), then no alerting output is generated (step 112).

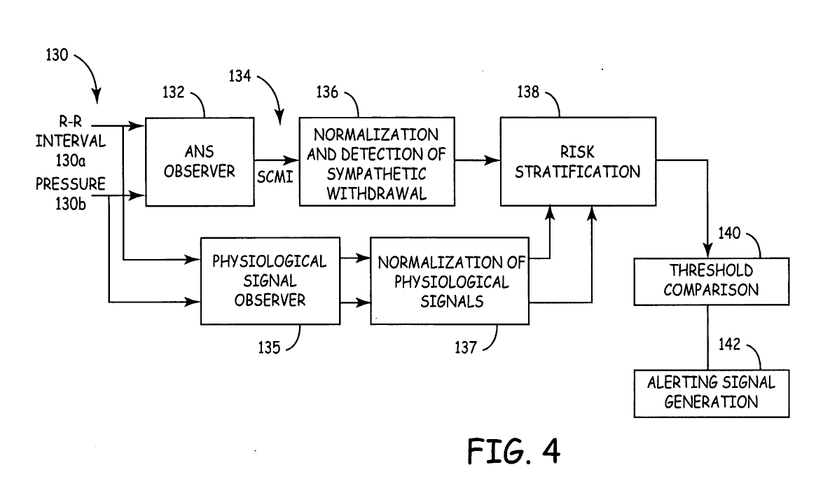

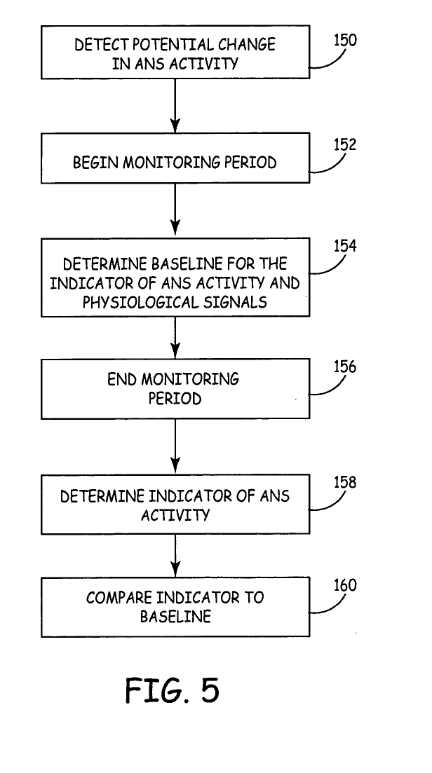

An indicator of ANS activity may be determined in accordance with step 102 in many ways. The techniques described below in conjunction with FIGS. 4 and 5 represent examples, and are not the only possible techniques for determining indicators of ANS activity.

FIG. 4 is a block diagram including functional blocks that illustrate the logic followed by processor 40 when determining an indicator of ANS activity. In particular, FIG. 4 illustrates an example of a technique for receiving R-R interval and pressure signal inputs 130, determining an indicator of ANS activity based on those inputs, assessing the risk of VVS, and, if appropriate, alerting the patient of the onset of VVS.

Analysis of ANS activity includes receiving at least two physiological signals 130 that include at least one indicator of ANS activity. In FIG. 4, R-R interval signal 130a and blood pressure signal 130b are shown as examples of physiological signals 130. As described above, the R-R interval signal 130a and the blood pressure signal 130b may be derived from the plethysmographic signal sensed by light detectors 25, because variations of optical tissue characteristics are related to variations in subcutaneous blood flow.

An ANS observer (functional block 132) receives R-R interval and pressure signal inputs 130. Using signal processing techniques, the ANS observer derives one or more signals, such as a sympathetic cardiac modulation index (SCMI) signal 134, that indicate ANS activity from physiological signals 130. SCMI signal 134 is representative of the sympatho-vagal balance, with a high SCMI indicating cardiac sympathetic dominance, and a low SCMI indicating cardiac parasympathetic dominance. SCMI signal 134 is one example of an indicator of ANS activity; in other embodiments, the ANS observer (functional block 132) may generate distinct signals reflecting sympathetic nervous activity and parasympathetic nervous activity.

As described above, the indicator of ANS activity is derived from physiological signals 130 using various signal processing techniques. For example, blind source separation (BSS) is a well-known technique for determining original signals from mixtures of signals. By applying BSS, the ANS observer (functional block 132) separates or “demixes” physiological signals 130 to derive a signal or signals related to the sympathetic and parasympathetic subsystems (e.g., SCMI signal 134). Signals 130 may be filtered prior to BSS. Determining one or more ANS indicators using BSS is advantageous in that it is a robust technique for recovery of signals from noisy sources and it is suitable for recovery of temporally correlated signals, such as SCMI signal 134. Thus, BSS is well suited to detection of sympathetic withdrawal that may precede an episode of VVS.

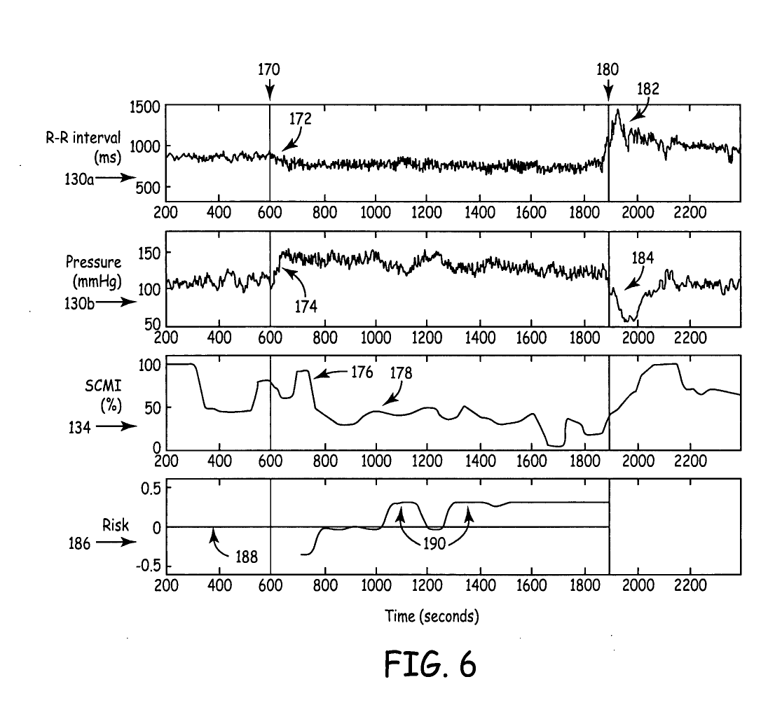

A monitoring period begins with the detection of a potential change in ANS activity that may lead to VVS (such as detection of a posture or activity transition by motion detecting device 30). During the monitoring period, an indicator of ANS activity is generated by normalizing SCMI signal 134 with respect to the signals observed during the monitoring period (functional block 136). This normalization technique (described below in connection with FIG. 6) helps make SCMI signal 134 subject-independent.

During the monitoring period, signals 130 are supplied to a physiological signal observer (functional block 135), which filters signals 130 and derives one or more measures of the signals, such as the mean and variance. Signals 130 received after the monitoring period are normalized with respect to the derived measures (functional block 137).

The probability that the patient will experience VVS is then estimated via risk stratification (functional block 138), based upon the normalized indicator or indicators of ANS activity and the normalized physiological signals. The risk of VVS is then compared to a threshold (functional block 140). When the risk exceeds the threshold, warning device 50 generates an alerting signal 142 (functional block 142) to the patient. In one embodiment, the threshold is a programmable parameter representing a percentage of likelihood, or an indicator of positive or negative risk.

FIG. 5 is a flow diagram illustrating a technique for normalization depicted in FIG. 4 as functional block 136. In general, this normalization technique includes determining a baseline of ANS activity during a monitoring period that follows detection of a potential change in ANS activity (such as detection of a posture or activity transition by motion detecting device 30). Persons at risk of recurrent episodes of VVS typically do not experience fainting for several minutes after the change in ANS activity. During this time, sympathetic nervous activity is compared to the baseline activity to see whether a withdrawal of sympathetic nervous activity occurs. In general, the baseline represents a cumulative measure of an indicator of ANS activity and physiological signals, rather than a single measurement taken at a single time during the monitoring period.

Following a detected potential change in ANS activity (150), the monitoring period begins (152). A typical monitoring period may be, for example, from 180 to 200 seconds, during which the risk of VVS onset is low. During the monitoring period, processor 40 determines a baseline indicator of physiological signals 130 (FIG. 4) and ANS activity (154). The baseline value of ANS activity may be determined by the techniques described above. That is, the baseline value of ANS activity is determined by receiving two physiological signals that indicate ANS activity, and applying BSS to demix the sympathetic and parasympathetic components or to recover a single signal that reflects ANS activity (e.g., SCMI signal 134 in FIG. 4). Processor 40 computes a mean and variance of the indicator of ANS activity during the monitoring period to serve as the baseline that is stored in memory unit 60 of device 10. Processor 40 also computes a mean and variance of the physiological signals 130.

When the monitoring period ends (156), processor 40 determines the indicator of ANS activity (158). Once again, the indicator of ANS activity may be determined by a technique such as receiving two physiological signals that indicate ANS activity, and applying BSS to recover one or more indicators of ANS activity. The physiological signals may be normalized to the baseline determined during the monitoring period. Processor 40 further compares the indicator of ANS activity to the baseline (160). Based on this comparison, processor 40 estimates the probability that the patient will experience VVS. This probability is compared to a threshold, and an alerting signal is generated by warning device 50 as a function of that comparison.

FIG. 6 includes four timelines on the same time scale to illustrate an example of operation of the invention. Timelines 130a and 130b represent the R-R interval and a blood pressure (such as arterial blood pressure), respectively, as derived from the plethysmographic signals received by device 10. Time reference 170 at approximately t=600 seconds represents the detection of a potential change in ANS activity. The potential change in ANS activity (for example, due to a posture change assessed by motion detection device 30) triggers the beginning of the monitoring period. It also triggers analysis of the R-R interval and the blood pressure signal to determine a baseline indicator of ANS activity. In FIG. 6, the duration of the monitoring period is 200 seconds.

A potential change in ANS activity occurs when the R-R interval exhibits a decrease (172), meaning that the heart of the patient is beating more rapidly. The blood pressure increases (174) as a result of the potential change in ANS activity. ANS activity, however, is not obvious from physiological signals such as the R-R interval and the blood pressure. By applying BSS, processor 40 may separate the physiological signals to reconstruct the sympathetic and parasympathetic signal components. In FIG. 6, ANS activity is represented by a single index, such as SCMI signal 134 produced by the ANS observer in FIG. 4. In general, a high SCMI indicates cardiac sympathetic dominance, and a low SCMI indicates cardiac parasympathetic dominance.

Following the detection of a potential change in ANS activity, the patient exhibits notable sympathetic activity 176 during the monitoring period. Near the end of the monitoring period or following the monitoring period, however, the sympathetic activity exhibits a decline 178. The patient does not experience VVS immediately as a result of this decline, but experiences VVS at approximately t=1900 seconds (time reference 180), when the patient experiences a marked increase in R-R interval 182 (i.e., a marked drop in heart rate), and a marked drop in blood pressure 184.

By monitoring sympathetic withdrawal with respect to the baseline determined during the monitoring period, processor 40 assesses the risk 186 that the patient will experience VVS. Any scale of risk may be employed. In FIG. 6, risk is rated as positive or negative, with zero representing the threshold 188.

By generating an alerting signal when the patient is at positive risk 190 of VVS, injuries associated with an episode of VVS at time reference 180 may be avoided. Notably, a positive risk 190 of VVS manifests itself well before the actual onset of VVS. Consequently, the patient may have enough time before fainting to sit down to avoid falling or to stop driving to avoid an automobile accident, for example.

In summary, the present invention is a warning device configured to be worn in contact with human tissue to detect vasovagal syncope (VVS) in a patient. The device includes a photoplethysmographic sensor operable to measure a physiological signal through the human tissue. The device also includes a processor to derive an indicator of an autonomous nervous system (ANS) activity from the physiological signal and to estimate a probability that the patient will experience VVS as a function of the indicator. The device provides advance warning to help patients avoid injuries associated with an episode of VVS.

Although the present invention has been described with reference to preferred embodiments, workers skilled in the art will recognize that changes may be made in form and detail without departing from the spirit and scope of the invention. For example, while the invention has been described with respect to a device worn on the wrist, it will be appreciated that the VVS detector can be designed to be worn on other parts of the body such as a patient's finger, nail, or ear lobe.

1. A device configured to detect vasovagal syncope (VVS), the device comprising:
a photoplethysmographic sensor which is operable to measure a plethysmographic signal; and
a processor to derive an indicator of an autonomous nervous system (ANS) activity from the plethysmographic signal and to estimate a probability of VVS as a function of the indicator.

2. The device of claim 1, wherein the plethysmographic signal is representative of at least one of a heart rate, a heart interval, and a blood pressure.

3. The device of claim 1, wherein the photoplethysmographic sensor comprises:
a radiation source to emit radiant energy; and
a plurality of detectors to detect an intensity of the radiant energy after propagation through a medium.

4. The device of claim 1, wherein the indicator of the ANS activity comprises a value representative of a sympatho-vagal balance.

5. The device of claim 1, wherein the indicator of the ANS activity includes at least one of a cardiac sympathetic nervous activity value and a cardiac parasympathetic nervous activity value.

6. The device of claim 1, and further comprising:
an alarm for providing an output when the probability of VVS exceeds a threshold probability.

7. The device of claim 1, wherein the alarm produces an auditory output.

8. The device of claim 1, wherein the alarm produces a visual output.

9. The device of claim 1, wherein the device includes a wrist strap.

10. A device configured for wearing adjacent to tissue of a patient to detect vasovagal syncope (VVS) in the patient and alert the patient of the VVS, the device comprising:
a light source for transmitting radiant energy into the human tissue;
light detectors for detecting an intensity of the radiant energy after propagation through the human tissue;
a processor for deriving a plethysmographic signal from the detected intensity of the radiant energy, deriving an indicator of an autonomous nervous system (ANS) activity from the plethysmographic signal, and estimating a probability that the patient will experience VVS as a function of the indicator; and
an alarm for providing an output as a function of the estimated probability that the patient will experience VVS.

11. The device of claim 10, wherein the indicator of the ANS activity comprises a measure of sympatho-vagal balance.

12. The device of claim 10, wherein the indicator of the ANS activity includes a measure of at least one of cardiac sympathetic nervous activity and cardiac parasympathetic nervous activity.

13. The device of claim 10, wherein the processor further derives a baseline indicator of ANS activity and stores the baseline indicator of ANS activity in a memory.

14. The device of claim 13, wherein the processor is further configured to compare the indicator to the baseline indicator and to estimate the probability that the patient will experience VVS as a function of the comparison.

15. A method for detecting vasovagal syncope (VVS) in a patient, the method comprising:
directing radiant energy into tissue of the patient;
measuring an intensity of the radiant energy after propagation through the tissue;
deriving a physiological signal from the measurement;
deriving an indicator of an autonomous nervous system (ANS) activity from the physiological signal; and
estimating a probability that the patient will experience VVS as a function of the indicator.

16. The method of claim 15, wherein deriving an indicator of an ANS activity from the physiological signal comprises:
deriving a sympathetic activity indicator from the physiological signal;
deriving a parasympathetic activity indicator from the physiological signal; and
estimating a relative magnitude of the sympathetic activity indicator in comparison to the parasympathetic activity indicator.

17. The method of claim 15, wherein deriving an indicator of an ANS activity comprises:
determining a baseline indicator of the ANS activity; and
comparing the indicator to the baseline indicator.

18. The method of claim 17, wherein determining a baseline indicator of the ANS activity comprises:
commencing a monitoring period in response to a detected posture transition; and
determining the baseline indicator of the ANS activity during the monitoring period.

19. The method of claim 18, and further comprising:
sensing at least one physiological signal during the monitoring period;
generating a measure of the physiological signal as a function of the sensing during the monitoring period;
sensing the physiological signal following the monitoring period; and
normalizing the physiological signal following the monitoring period with respect to the measure.

20. The method of claim 15, and further comprising:
generating an output when the probability that the patient will experience VVS exceeds a threshold probability.
